(19) United States
(12) Patent Application Publication
(10) Pub. No.: US 2024/0357738 A1
(43) Pub. Date: Oct. 24, 2024

(54) STRETCHABLE WIRING BOARD

(71) Applicant: Murata Manufacturing Co., Ltd., Nagaokakyo-shi (JP)

(72) Inventors: Ryo ASAI, Nagaokakyo-shi (JP); Hayato KATSU, Nagaokakyo-shi (JP); Keisuke NISHIDA, Nagaokakyo-shi (JP); Takayoshi OBATA, Nagaokakyo-shi (JP)

(21) Appl. No.: 18/761,690

(22) Filed: Jul. 2, 2024

Related U.S. Application Data
(63) Continuation of application No. PCT/JP2022/040172, filed on Oct. 27, 2022.

(30) Foreign Application Priority Data
Jan. 4, 2022 (JP) 2022-000247

(51) Int. Cl. H05K 1/02

(52) U.S. Cl. CPC H05K 1/0283

(57) ABSTRACT

A stretchable wiring board that includes: a main body; a stretchable first wiring on the main body; and a stretchable second wiring on the main body and connected to the stretchable first wiring, wherein at least one of a first peeling strength between the main body and the stretchable first wiring and a second peeling strength between the main body and the stretchable second wiring is smaller than a third peeling strength between the stretchable first wiring and the stretchable second wiring.

### CROSS REFERENCE TO RELATED APPLICATIONS

The present application is a continuation of International application No. PCT/JP2022/040172, filed Oct. 27, 2022, which claims priority to Japanese Patent Application No. 2022-000247, filed Jan. 4, 2022, the entire contents of each of which are incorporated herein by reference.

### TECHNICAL FIELD

The present disclosure relates to a stretchable wiring board.

### BACKGROUND ART

A conventional stretchable wiring board is described in Japanese Patent Application Laid-Open No. 2019-140292 (Patent Document 1). The stretchable wiring board includes a first wiring and a second wiring on a first surface of a stretchable substrate, and the first wiring and the second wiring are electrically connected with a connection portion interposed therebetween.
Patent Document 1: Japanese Patent Application Laid-Open No. 2019-140292

### SUMMARY OF THE DISCLOSURE

When the stretchable wiring board is attached to a flexible and moving object such as a living body in some cases, stress from multiple directions may be applied. In such a case, a problem arises in that the connection portion between the first wiring and the second wiring is broken and disconnection occurs.

Therefore, an object of the present disclosure is to provide a stretchable wiring board capable of suppressing disconnection when the stretchable wiring board is attached to a flexible and moving object such as a living body.

In order to solve the above problem, a stretchable wiring board according to an aspect of the present disclosure includes: a main body; a stretchable first wiring on the main body; and a stretchable second wiring on the main body and connected to the stretchable first wiring, wherein a first peeling strength of the main body is smaller than a second peeling strength between the stretchable first wiring and the stretchable second wiring.

In the present specification, lamination includes not only a case where the first wiring and the second wiring are disposed on the main body (hereinafter, also referred to as “stress relaxation portion”), but also a case where the main body (stress relaxation portion) includes a plurality of members and the first wiring and the second wiring are disposed between the plurality of members.

In the present specification, the peeling strength in the main body (stress relaxation portion) means the peeling strength between the main body (stress relaxation portion) and the first wiring and the peeling strength between the main body (stress relaxation portion) and the second wiring, and means the peeling strength between two adjacent members when the main body (stress relaxation portion) includes a plurality of members, in addition to the above two peeling strengths.

According to the aspect, the peeling strength in the main body (stress relaxation portion) is smaller than the peeling strength between the first wiring and the second wiring. Therefore, when the stretchable wiring board is bent, at least one of the portion between the main body (stress relaxation portion) and the first wiring, the portion between the main body (stress relaxation portion) and the second wiring, and when the main body (stress relaxation portion) includes a plurality of members, the portion between two adjacent members is peeled off, so that the stress is released, and the peeling of the first wiring and the second wiring is suppressed. Therefore, the electrical connection between the first wiring and the second wiring can be maintained.

Preferably, in one embodiment of the stretchable wiring board, at least one of a third peeling strength between the main body and the stretchable first wiring and a fourth peeling strength between the main body and the stretchable second wiring is smaller than the second peeling strength between the stretchable first wiring and the stretchable second wiring.

According to the embodiment, at least one of the peeling strength between the main body (stress relaxation portion) and the first wiring and the peeling strength between the main body (stress relaxation portion) and the second wiring is smaller than the peeling strength between the first wiring and the second wiring. Therefore, when the stretchable wiring board is bent, at least one of the interface between the main body (stress relaxation portion) and the first wiring and the interface between the main body (stress relaxation portion) and the second wiring is peeled off, so that the stress is released, and the peeling of the first wiring and the second wiring is suppressed. Therefore, the electrical connection between the first wiring and the second wiring can be maintained.

Preferably, in one embodiment of the stretchable wiring board, the main body includes a plurality of members laminated on each other, and at least one of a third peeling strength between the main body and the stretchable first wiring, a fourth peeling strength between the main body and the stretchable second wiring, and a fifth peeling strength between two adjacent members of the plurality of members is smaller than the second peeling strength between the stretchable first wiring and the stretchable second wiring.

According to the embodiment, the main body (stress relaxation portion) includes a plurality of members laminated on each other, and at least one of a peeling strength between the main body (stress relaxation portion) and the first wiring, a peeling strength between the main body (stress relaxation portion) and the second wiring, and a peeling strength between two adjacent members is smaller than the peeling strength between the first wiring and the second wiring. Therefore, when the stretchable wiring board is bent, at least one of the interface between the main body (stress relaxation portion) and the first wiring, the interface between the main body (stress relaxation portion) and the second wiring, and the interface between two adjacent members is peeled off, so that the stress is released, and the peeling of the first wiring and the second wiring is suppressed. Therefore, the electrical connection between the first wiring and the second wiring can be maintained.

Preferably, in one embodiment of the stretchable wiring board, a third peeling strength between the main body and the stretchable first wiring is different from a fourth peeling strength between the main body and the stretchable second wiring.

According to the embodiment, the peeling strength between the main body (stress relaxation portion) and the first wiring is different from the peeling strength between the main body (stress relaxation portion) and the second wiring. Therefore, when the stretchable wiring board is bent, one of the first wiring and the second wiring is first peeled off from the main body (stress relaxation portion), and the other thereof is kept in contact with the main body (stress relaxation portion). Therefore, peeling between the substrate and the wiring can be minimized, and at least a part of the wiring can be protected by the main body (stress relaxation portion) Since at least a part of the wiring and the main body (stress relaxation portion) maintain contact with each other, penetration of moisture can be prevented, and reliability of the stretchable wiring board can be maintained.

Preferably, in one embodiment of the stretchable wiring board, the main body includes a stretchable substrate, and the stretchable first wiring and the stretchable second wiring are on the stretchable substrate.

According to the embodiment, the main body (stress relaxation portion) includes a substrate having stretchability, and the first wiring and the second wiring are disposed on the substrate. Therefore, the shapes of the first wiring and the second wiring can be maintained while maintaining the stretchability of the stretchable wiring board.

Preferably, in one embodiment of the stretchable wiring board, the main body includes a waterproof layer.

According to the embodiment, the main body (stress relaxation portion) includes a waterproof layer having waterproofness. Therefore, penetration of moisture can be prevented, and reliability of the stretchable wiring board can be maintained.

Preferably, in one embodiment of the stretchable wiring board, the waterproof layer is between the stretchable substrate and the stretchable first wiring and the stretchable second wiring.

According to the embodiment, the waterproof layer having waterproofness is disposed between the substrate and the wirings. Therefore, penetration of moisture from the substrate side can be prevented, and reliability of the stretchable wiring board can be maintained.

Preferably, in one embodiment of the stretchable wiring board, a hard portion is further provided.

According to the embodiment, since the stretchable wiring board includes a hard portion, excessive deformation of the stretchable wiring board due to an external force can be suppressed.

Preferably, in one embodiment of the stretchable wiring board, wherein the hard portion covers a portion where the stretchable first wiring and the stretchable second wiring are connected to each other and is in contact with the stretchable substrate.

According to the embodiment, the hard portion covers a portion where the first wiring and the second wiring are connected to each other and is in contact with the substrate. Therefore, penetration of moisture can be prevented while suppressing excessive deformation of the substrate or the wiring, at a place where the shape of the substrate or the wiring needs to be maintained.

A stretchable wiring board according to an aspect of the present disclosure includes: a main body; a stretchable first wiring on the main body; a stretchable second wiring on the main body and connected to the stretchable first wiring; and a void portion located so as to absorb stress applied to the stretchable wiring board and suppress peeling of at least one of the stretchable first wiring and the stretchable second wiring.

According to the aspect, the stretchable wiring board has a void. Therefore, when the stretchable wiring board is bent, stress is absorbed by the void, so that the peeling of the first wiring and the second wiring can be suppressed. Therefore, the electrical connection between the first wiring and the second wiring can be maintained.

Preferably, in one embodiment of the stretchable wiring board, the void portion is located at least one of between the main body and the stretchable first wiring and between the main body and the stretchable second wiring.

According to the aspect, the void in the stretchable wiring board is located at least one of between the main body (stress relaxation portion) and the first wiring and between the main body (stress relaxation portion) and the second wiring. Therefore, when the stretchable wiring board is bent, stress is absorbed by the void located near the first wiring and the second wiring, so that the peeling of the first wiring and the second wiring can be suppressed. Therefore, the electrical connection between the first wiring and the second wiring can be maintained.

Preferably, in one embodiment of the stretchable wiring board, the main body includes a plurality of members laminated on each other, and the void portion is located at least one of between the main body and the stretchable first wiring, between the main body and the stretchable second wiring, and between two adjacent members of the plurality of members.

According to the aspect, the main body (stress relaxation portion) includes a plurality of members laminated on each other, and the void in the stretchable wiring board is located at least one of between the main body (stress relaxation portion) and the first wiring, between the main body (stress relaxation portion) and the second wiring, and between two adjacent members. Therefore, when the stretchable wiring board is bent, stress is absorbed by the void, so that the peeling of the first wiring and the second wiring can be suppressed. Therefore, the electrical connection between the first wiring and the second wiring can be maintained.

Preferably, in one embodiment of the stretchable wiring board, the main body includes a stretchable substrate, and the stretchable first wiring and the stretchable second wiring are on the stretchable substrate.

According to the embodiment, the main body (stress relaxation portion) includes a substrate having stretchability, and the first wiring and the second wiring are disposed on the substrate. Therefore, the shapes of the first wiring and the second wiring can be maintained while maintaining the stretchability of the stretchable wiring board.

Preferably, in one embodiment of the stretchable wiring board, the main body includes a waterproof layer.

According to the embodiment, the main body (stress relaxation portion) includes a waterproof layer having waterproofness. Therefore, when the stretchable wiring board includes a void, penetration of moisture can be prevented, and reliability of the stretchable wiring board can be maintained.

Preferably, in one embodiment of the stretchable wiring board, the waterproof layer is between the stretchable substrate and the stretchable first wiring and the stretchable second wiring.

According to the embodiment, the waterproof layer having waterproofness is disposed between the substrate and the wirings. Therefore, penetration of moisture from the substrate side can be prevented, and reliability of the stretchable wiring board can be maintained when the stretchable wiring board includes a void.

Preferably, in one embodiment of the stretchable wiring board, a hard portion is further provided.

According to the embodiment, since the stretchable wiring board includes a hard portion, excessive deformation of the stretchable wiring board due to an external force can be suppressed.

Preferably, in one embodiment of the stretchable wiring board, the hard portion covers a portion where the stretchable first wiring and the stretchable second wiring are connected to each other and is in contact with the stretchable substrate.

According to the embodiment, the hard portion covers a portion where the first wiring and the second wiring are connected to each other and is in contact with the substrate. Therefore, penetration of moisture can be prevented when the stretchable wiring board has a void while suppressing excessive deformation of the substrate or the wiring, at a place where the shape of the substrate or the wiring needs to be maintained.

According to the stretchable wiring board of an aspect of the present disclosure, disconnection can be suppressed when the stretchable wiring board is attached to a flexible and moving object such as a living body.

### BRIEF EXPLANATION OF THE DRAWINGS

FIG. 1 is a plan view of a stretchable wiring board.

FIG. 2 is an enlarged view of a portion A in FIG. 1, and is a plan view illustrating a first embodiment of the stretchable wiring board.

FIG. 3 is a sectional view taken along III-III of FIG. 2.

FIG. 4 is an enlarged sectional view illustrating a part of a second embodiment of the stretchable wiring board.

FIG. 5 is an enlarged sectional view illustrating a part of a third embodiment of the stretchable wiring board.

FIG. 6 is an enlarged sectional view illustrating a part of a fourth embodiment of the stretchable wiring board.

FIG. 7 is an enlarged sectional view illustrating a part of a fifth embodiment of the stretchable wiring board.

FIG. 8 is an enlarged sectional view illustrating a part of a sixth embodiment of the stretchable wiring board.

FIG. 9 is an enlarged sectional view illustrating a part of a seventh embodiment of the stretchable wiring board.

FIG. 10 is an enlarged sectional view illustrating a part of an eighth embodiment of the stretchable wiring board.

FIG. 11 is an enlarged sectional view illustrating a part of a ninth embodiment of the stretchable wiring board.

FIG. 12 is an enlarged sectional view illustrating a part of the ninth embodiment of the stretchable wiring board.

FIG. 13 is an enlarged sectional view illustrating a part of a tenth embodiment of the stretchable wiring board.

FIG. 14 is a sectional view taken along XIV-XIV of FIG. 13.

### DESCRIPTION OF THE PREFERRED EMBODIMENTS

Hereinafter, a stretchable wiring board according to an aspect of the present disclosure will be described in detail with reference to an illustrated embodiment. It is to be noted that the drawings include some schematic drawings, and do not reflect actual dimensions or ratios in some cases.

### First Embodiment

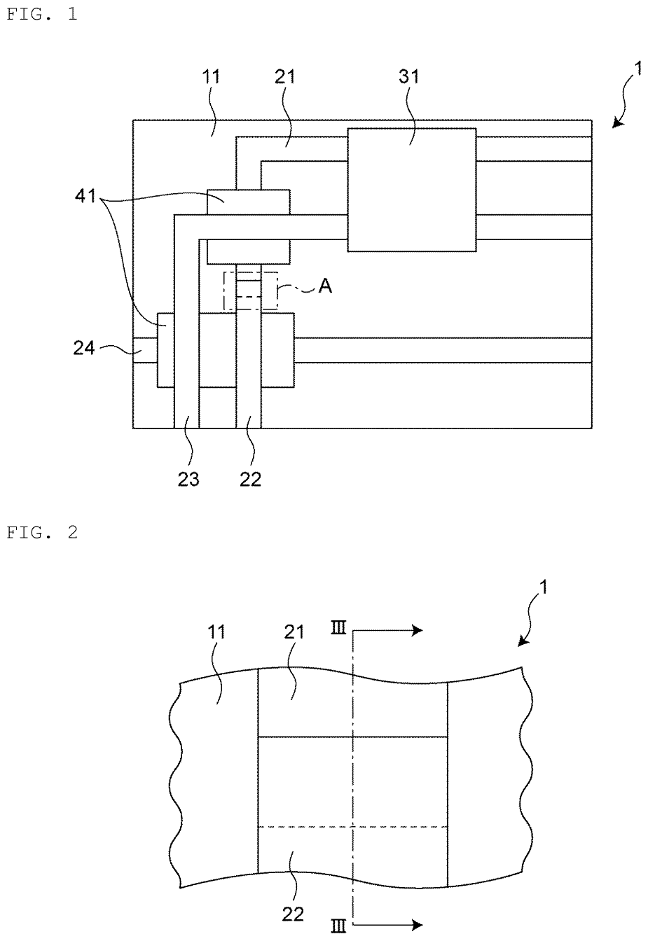

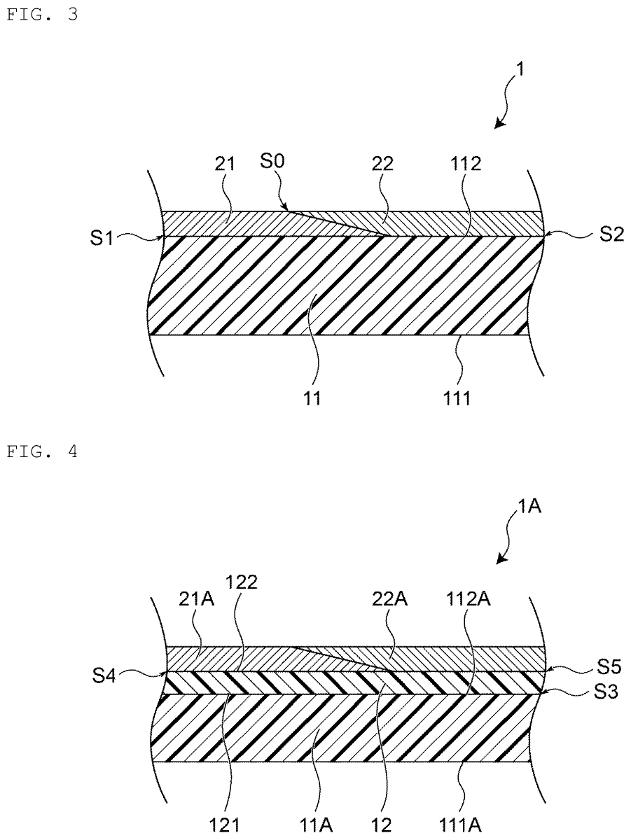

FIG. 1 is a plan view of a stretchable wiring board. FIG. 2 is an enlarged view of a portion A in FIG. 1, and is a plan view illustrating a first embodiment of the stretchable wiring board. FIG. 3 is a sectional view taken along III-III of FIG. 2. The stretchable wiring board is used, for example, to measure a biological signal by being brought into contact with a living body.

As illustrated in FIG. 1, a stretchable wiring board 1 includes a substrate 11, a first wiring 21, a second wiring 22, a third wiring 23, and a fourth wiring 24 provided on the substrate 11, and an electronic component 31. In FIG. 1, the first wiring 21 and the third wiring 23 are electrically connected to the electronic component 31. The first wiring 21 and the third wiring 23, the second wiring 22 and the fourth wiring 24, and the third wiring 23 and the fourth wiring 24 three-dimensionally intersect each other, respectively, and insulating layers 41 exist between the plurality of wirings in a region where the plurality of wirings three-dimensionally intersect each other. FIGS. 2 and 3 illustrate the substrate 11, the first wiring 21, and the second wiring 22, and the stretchable wiring board 1 includes the substrate 11, and the first wiring 21 and the second wiring 22 provided on the substrate 11. The substrate 11 corresponds to an example of the main body (stress relaxation portion).

The substrate 11 is formed of a stretchable resin material, for example, styrene resin, olefin resin, epoxy resin, urethane resin, acrylic resin, or silicone resin, and is preferably formed of urethane resin. Examples of the urethane resin include thermoplastic polyurethane (TPU). Examples of the styrene resin include styrene-butadiene-styrene copolymer resin (SBS).

A stretching ratio of the substrate 11 is preferably 50% or more. By setting the above stretching ratio, followability of the stretchable wiring board to a living body becomes excellent. Young's modulus of the substrate 11 is preferably 100 MPa or less, and more preferably 30 MPa or less. By setting the above Young's modulus, discomfort of the user can be reduced. A thickness of the substrate 11 is, for example, 0.1 to 100 μm.

The substrate 11 includes a first main surface 111 and a second main surface 112 facing each other.

The first wiring 21 and the second wiring 22 are formed of a conductive material. As the conductive material, for example, metal foil of silver, copper, nickel or the like may be used, or a mixture of metal powder of silver, copper, nickel or the like and elastomeric resin such as epoxy resin, urethane resin, acrylic resin, or silicone resin may be used. A thickness of the metal foil is preferably 0.01 μm to 10 μm, and an average particle size D50 of the metal powder is preferably 0.01 μm to 10 μm. A shape of the metal powder may be a spherical shape, a flat shape, an irregular shape having a protrusion, or the like. The first wiring 21 and the second wiring 22 may be stretchable. When the first wiring 21 and the second wiring 22 are stretchable, followability to a living body is improved.

A thickness of each of the first wiring 21 and the second wiring 22 is preferably 100 μm or less, more preferably 50 μm or less, and preferably 1 μm or more, more preferably 10 μm or more. The thinner the thickness of each of the first wiring 21 and the second wiring 22, the less the unevenness and the easier the lamination and the like. A width of each of the first wiring 21 and the second wiring 22 is preferably 100 μm to 10,000 μm, and more preferably 200 μm to 5,000 μm.

The first wiring 21 and the second wiring 22 are disposed on the second main surface 112 and extend along the second main surface 112. The first wiring 21 and the second wiring 22 are formed by screen printing, inkjet printing, dispensing, or etching of metal foil so as to be in direct contact with the second main surface 112. The first wiring and the second wiring may be covered with an insulating coating layer (not illustrated).

Here, “on the main surface” refers to not an absolute direction such as vertically upward defined in the direction of gravity but a direction toward the outside between the outside and the inside of the substrate having the main surface as a boundary. Therefore, “on the main surface” is a relative direction determined by a direction of the main surface. Further, “on” a certain element includes not only a position immediately above and in contact with the element (on) but also an upper position away from the element, that is, an upper position with another object on the element interposed between them or an upper position with a space between them (above).

Further, “on the layer” refers not to an absolute one direction such as a vertical upward defined in the direction of gravity, but to a direction toward an outside out of an outside and an inside of the substrate with the main surface of the layer being a boundary. Therefore, “on the layer” is a relative direction determined by a direction of the main surface of the layer.

The first wiring 21 is in contact with and electrically connected to the second wiring 22. A part of the first wiring 21 and a part of the second wiring 22 may overlap. In FIGS. 2 and 3, one end of the second wiring 22 in the extending direction is disposed so as to overlap one end of the first wiring 21 in the extending direction. In FIGS. 2 and 3, the first wiring 21 and the second wiring 22 are constituted by a straight portion, but are not limited to this, and may have a corner portion and a curved portion. Note that a region where the first wiring 21 and the second wiring 22 are in contact with each other preferably has an area of 0.03 mm² or more in top view, and preferably has a length of 200 μm or more in the extending direction of the wiring. The reliability of connection can be further enhanced by increasing the area of the contact region.

At least one of a peeling strength of an interface S1 between the substrate 11 and the first wiring 21 and a peeling strength of an interface S2 between the substrate 11 and the second wiring 22 is smaller than a peeling strength of an interface S0 between the first wiring 21 and the second wiring 22. The peeling strength represents a resistance force against peeling when two layers in contact with each other are tried to be peeled off, and a higher peeling strength indicates that it is more difficult to peel off the two layers. Therefore, when the stretchable wiring board 1 is bent and stress is applied in a direction orthogonal to the second main surface 112, the stress is released by first peeling at least one of the interface S1 between the substrate 11 and the first wiring 21 and the interface S2 between the substrate 11 and the second wiring 22, and the peeling of the first wiring 21 and the second wiring 22 is suppressed. Therefore, the electrical connection between the first wiring 21 and the second wiring 22 can be maintained.

The peeling strength between the substrate 11 and the first wiring 21 can be measured in accordance with JIS K 5600 May 6, and is preferably 1 to 4. When the classification of the peeling strength is 4 or less, the substrate 11 and the first wiring 21 can follow the movement of a living body without being peeled off from each other. When the classification of the peeling strength is 1 or more and stress is applied in a direction orthogonal to the second main surface 112, the stress can be absorbed by first peeling between the substrate 11 and the first wiring 21, and peeling between the first wiring 21 and the second wiring 22 can be suppressed. Therefore, the electrical connection between the first wiring 21 and the second wiring 22 can be maintained.

A peeling strength between the first wiring 21 and the second wiring 22 is preferably 0.1 N/10 mm or more, and more preferably 0.2 N/10 mm or more. For example, the peeling strength can be measured by the following method.

### [Method for Measuring Peeling Strength Between First Wiring and Second Wiring]

A first wiring is formed on a resin substrate, and a part of the first wiring is covered with a release film. Next, a second wiring is formed on the first wiring to cover at least a part of the release film. The release film is removed, and the first wiring and the second wiring are molded to have a width of 10 mm, thereby preparing a test piece. The prepared test piece is subjected to a 180-degree peeling test at a peeling rate of 1 mm/s.

The fact that the peeling strength between the substrate 11 and the first wiring 21 is smaller than the peeling strength between the first wiring 21 and the second wiring 22 can be confirmed by performing a peeling test defined in JIS K5600-5-6 in a region where the first wiring 21 and the second wiring 22 are in contact with each other, in which the substrate 11 and the first wiring 21 are peeled off from each other, and contact between the first wiring 21 and the second wiring 22 is maintained.

A peeling strength between the substrate 11 and the second wiring 22 is smaller than a peeling strength between the first wiring 21 and the second wiring 22. Therefore, when stress is applied in a direction orthogonal to the second main surface 112, the stress is released by first peeling between the substrate 11 and the second wiring 22, and peeling between the first wiring 21 and the second wiring 22 is suppressed. Therefore, the electrical connection between the first wiring 21 and the second wiring 22 can be maintained.

The peeling strength between the substrate 11 and the second wiring 22 can be measured in accordance with JIS K 5600 May 6, and is preferably 1 to 4. When the classification of the peeling strength is 4 or less, the substrate 11 and the second wiring 22 can follow the movement of a living body without being peeled off from each other. When the classification of the peeling strength is 1 or more and stress is applied in a direction orthogonal to the second main surface 112, the stress can be absorbed by first peeling between the substrate 11 and the second wiring 22, and peeling between the first wiring 21 and the second wiring 22 can be suppressed. Therefore, the electrical connection between the first wiring 21 and the second wiring 22 can be maintained.

The fact that the peeling strength between the substrate 11 and the second wiring 22 is smaller than the peeling strength between the first wiring 21 and the second wiring 22 can be confirmed by performing a peeling test defined in JIS K5600-5-6 in a region where the first wiring 21 and the second wiring 22 are in contact with each other, in which the substrate 11 and the second wiring 22 are peeled off from each other, and contact between the first wiring 21 and the second wiring 22 is maintained.

The peeling strength between the substrate 11 and the first wiring 21 is preferably different from the peeling strength between the substrate 11 and the second wiring 22. Therefore, when stress is applied in a direction orthogonal to the second main surface 112, one of the first wiring 21 and the second wiring 22 is first peeled off from the substrate 11, peeling between the substrate and the wiring is minimized, and the other thereof is kept in contact with the substrate 11. Therefore, at least a part of the wiring is protected by the substrate 11. Since at least a part of the wiring and the substrate 11 maintain contact with each other, penetration of moisture can be prevented, and reliability of the stretchable wiring board 1 can be maintained.

For example, a peeling strength between the substrate 11 and the second wiring 22 is smaller than a peeling strength between the substrate 11 and the first wiring 21.

The peeling strength between the substrate 11 and the first wiring 21 or the second wiring 22 can be adjusted by irradiating the substrate 11 with ultraviolet rays before forming the first wiring 21 or the second wiring 22 on the substrate 11 or by forming a release agent layer provided in contact with the second main surface 112.

In the present embodiment, the substrate 11 and the first wiring 21, and the substrate 11 and the second wiring 22 are in contact with each other, respectively, but the present disclosure is not limited thereto, and any one of the interface between the substrate 11 and the first wiring 21 and the interface between the substrate 11 and the second wiring 22 may be peeled off. In this case, a void may exist at least one of between the substrate 11 and the first wiring 21 and between the substrate 11 and the second wiring 22 at the peeled portion.

### Second Embodiment

FIG. 4 is an enlarged sectional view illustrating a part of a second embodiment of the stretchable wiring board, and specifically corresponds to FIG. 3. The second embodiment is different from the first embodiment in that a buffer layer is further provided and the first wiring and the second wiring are disposed on the buffer layer. This different configuration will be described below. The other configurations are the same as those of the first embodiment, denoted by the same reference symbols as those of the first embodiment, and omitted from description.

As illustrated in FIG. 4, a stretchable wiring board 1A of the second embodiment includes a buffer layer 12 laminated on a second main surface 112A of a substrate 11A and having a third main surface 121 and a fourth main surface 122. A first wiring 21A and a second wiring 22A are disposed on the fourth main surface 122 and extend along the fourth main surface 122. Thus, the first wiring 21A and the second wiring 22A can be protected by the buffer layer 12. The substrate 11A and the buffer layer 12 correspond to an example of a plurality of members included in the main body (stress relaxation portion).

The buffer layer 12 is formed of a resin material, for example, epoxy resin, urethane resin, acrylic resin, silicone resin, phenol resin, or polyimide resin, and may contain a glass fiber and a paper fiber.

The buffer layer 12 may be stretchable. A stretching ratio of the buffer layer 12 is preferably 5% or more. This makes it easy to follow a living body. Young's modulus of the buffer layer 12 is preferably 100 to 1000 MPa. This makes it possible to adjust the ease of peeling between the substrate 11A and the buffer layer 12 to an appropriate range. A thickness of the buffer layer 12 is, for example, 5 to 30 μm.

The buffer layer 12 preferably has waterproofness. As a result, penetration of moisture can be prevented, and reliability of the stretchable wiring board 1A can be maintained. In the present specification, the buffer layer 12 corresponds to a plurality of members included in the main body (stress relaxation portion), and when the buffer layer 12 has waterproofness, the buffer layer 12 corresponds to the waterproof layer.

The buffer layer 12 includes the third main surface 121 and the fourth main surface 122 facing each other.

At least one of a peeling strength of an interface S3 between the substrate 11A and the buffer layer 12, a peeling strength of an interface S4 between the buffer layer 12 and the first wiring 21A, and a peeling strength of an interface S5 between the buffer layer 12 and the second wiring 22A is smaller than the peeling strength of an interface S0 between the first wiring 21A and the second wiring 22A. Therefore, when stress is applied in a direction orthogonal to the fourth main surface 122, at least one of the interface S3 between the substrate 11A and the buffer layer 12, the interface S4 between the buffer layer 12 and the first wiring 21A, and the interface S5 between the buffer layer 12 and the second wiring 22A is first peeled off, and the contact between the first wiring 21A and the second wiring 22A can be protected. Thus, the first wiring 21A and the second wiring 22A are protected by the buffer layer 12, and the electrical connection between the first wiring 21A and the second wiring 22A can be maintained.

A peeling strength between the buffer layer 12 and the second wiring 22A is smaller than a peeling strength between the first wiring 21A and the second wiring 22A. Therefore, when stress is applied in a direction orthogonal to the fourth main surface 122, the stress is released by peeling between the buffer layer 12 and the second wiring 22A, and peeling between the first wiring 21A and the second wiring 22A is suppressed. Therefore, the electrical connection between the first wiring 21A and the second wiring 22A can be maintained.

The peeling strength between the substrate 11A and the buffer layer 12 can be measured in accordance with JIS K 5600 May 6, and is preferably 1 to 4. When the classification of the peeling strength is 4 or less, the substrate 11A and the buffer layer 12 can follow the movement of a living body without being peeled off from each other. When the classification of the peeling strength is 1 or more and stress is applied in a direction orthogonal to the fourth main surface 122, the stress can be absorbed by first peeling between the substrate 11A and the buffer layer 12, and peeling between the first wiring 21A and the second wiring 22A can be suppressed.

The peeling strength between the substrate 11A and the buffer layer 12 can be adjusted by irradiating the substrate 11A with ultraviolet rays before forming the buffer layer 12 on the substrate 11A or by forming a release agent layer provided in contact with the second main surface 112A.

The peeling strength between the buffer layer 12 and the first wiring 21 is different from the peeling strength between the buffer layer 12 and the second wiring 22. Therefore, when the stretchable wiring board is bent and stress is applied in a direction orthogonal to the fourth main surface 122A, one of the first wiring 21A and the second wiring 22A is first peeled off from the buffer layer 12, peeling between the buffer layer 12 and the wiring is minimized, and the other thereof is kept in contact with the buffer layer 12. Therefore, at least a part of the wiring is protected by the buffer layer 12. Since at least a part of the wiring and the buffer layer 12 maintain contact with each other, penetration of moisture can be prevented, and reliability of the stretchable wiring board 1 can be maintained.

In the present embodiment, the substrate 11A and the buffer layer 12, and the buffer layer 12 and the first wiring 21A are in contact with each other, respectively, but the present disclosure is not limited thereto, and any one of the interface between the substrate 11A and the buffer layer 12 and the interface between the buffer layer 12 and the first wiring 21A may be peeled off. In this case, a void may exist any one of between the substrate 11A and the buffer layer 12 and between the buffer layer 12 and the first wiring 21A at the peeled portion. Since an effect of the other configurations are the same as that of the first embodiment, description of the effect will be omitted.

### Third Embodiment

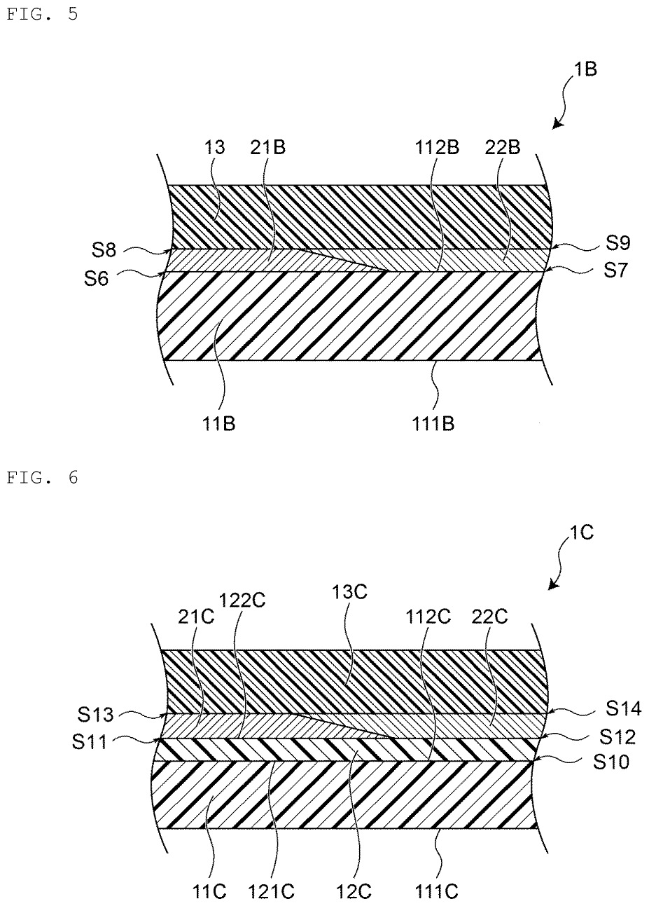

FIG. 5 is an enlarged sectional view illustrating a part of a third embodiment of the stretchable wiring board, and specifically corresponds to FIG. 3. The third embodiment is different from the first embodiment in that a first cover layer is further provided. This different configuration will be described below. The other configurations are the same as those of the first embodiment, denoted by the same reference symbols as those of the first embodiment, and omitted from description.

As illustrated in FIG. 5, a stretchable wiring board 1B of the third embodiment further includes a first cover layer 13 laminated on a second main surface 112B. A first wiring 21B and a second wiring 22B are disposed between a substrate 11B and the first cover layer 13. Thus, the first wiring 21B and the second wiring 22B can be protected. The substrate 11B and the first cover layer 13 correspond to an example of members included in the main body (stress relaxation portion).

The first cover layer 13 is formed of a resin material, for example, epoxy resin, urethane resin, acrylic resin, silicone resin, phenol resin, or polyimide resin.

The first cover layer 13 may be stretchable. A stretching ratio of the first cover layer 13 is preferably 5% or more. This makes it easy to follow a living body. Young's modulus of the first cover layer 13 is preferably 10 to 1000 MPa. Thus, the first wiring 21B and the second wiring 22B are easily protected. A thickness of the first cover layer 13 is, for example, 5 to 30 μm.

The first cover layer 13 preferably has waterproofness. As a result, penetration of moisture can be prevented, and reliability of the stretchable wiring board 1B can be maintained.

In a section orthogonal to the extending direction of the first wiring 21B, the first cover layer 13 preferably covers a portion where the first wiring 21B and the substrate 11B are not in contact with each other in the periphery of the first wiring 21B.

At least one of a peeling strength of an interface S6 between the substrate 11B and the first wiring 21B, a peeling strength of an interface S7 between the substrate 11B and the second wiring 22B, a peeling strength of an interface S8 between the first wiring 21B and the first cover layer 13, and a peeling strength of an interface S9 between the second wiring 22B and the first cover layer 13 is smaller than a peeling strength of an interface so between the first wiring 21B and the second wiring 22B. Therefore, when stress is applied in a direction orthogonal to the second main surface 112B, at least one of the interface S6 between the substrate 11B and the first wiring 21B, the interface S7 between the substrate 11B and the second wiring 22B, the interface S8 between the first wiring 21B and the first cover layer 13, and the interface S9 between the second wiring 22B and the first cover layer 13 is first peeled off, and peeling between the first wiring 21B and the second wiring 22B is suppressed. Thus, the first wiring 21B and the second wiring 22B are protected by the first cover layer 13, and the electrical connection between the first wiring 21B and the second wiring 22B can be maintained.

A peeling strength between the first cover layer 13 and the second wiring 22B is smaller than a peeling strength between the first wiring 21B and the second wiring 22B. Therefore, when stress is applied in a direction orthogonal to the second main surface 112B, the first cover layer 13 and the second wiring 22B are peeled off from each other, and peeling between the first wiring 21B and the second wiring 22B is suppressed. Thus, the first wiring 21B and the second wiring 22B are protected by the first cover layer 13, and the electrical connection between the first wiring 21B and the second wiring 22B can be maintained.

The peeling strength between the first cover layer 13 and the first wiring 21B is different from the first cover layer 13 and the second wiring 22B. Therefore, when stress is applied in a direction orthogonal to the second main surface 112B, one of the first wiring 21B and the second wiring 22B is first peeled off from the first cover layer 13, and the other thereof is kept in contact with the first cover layer 13. Therefore, at least a part of the wiring is protected by the first cover layer 13. Thus, penetration of moisture can be prevented, and reliability of the stretchable wiring board 1B can be maintained.

A peeling strength between the substrate 11B and the first cover layer 13 is smaller than a peeling strength between the first wiring 21B and the second wiring 22B. Therefore, when stress is applied in a direction orthogonal to the second main surface 112B, the substrate 11B and the first cover layer 13 are first peeled off from each other, peeling between the first cover layer 13 and the wiring is minimized, and peeling between the first wiring 21B and the second wiring 22B is suppressed. Thus, the first wiring 21B and the second wiring 22B are protected by the first cover layer 13, and the electrical connection between the first wiring 21B and the second wiring 22B can be maintained.

The peeling strength between the first cover layer 13 and the first wiring 21B, the peeling strength between the first cover layer 13 and the second wiring 22B, and the peeling strength between the substrate 11B and the first cover layer 13 can all be measured in accordance with JIS K 5600 May 6. The peeling strength between the first cover layer 13 and the first wiring 21B and the peeling strength between the first cover layer 13 and the second wiring 22B are each preferably 0 to 4. The peeling strength between the substrate 11B and the first cover layer 13 is preferably 0 to 4.

The peeling strength between the first cover layer 13 and the first wiring 21B, the peeling strength between the first cover layer 13 and the second wiring 22B, and the peeling strength between the substrate 11B and the first cover layer 13 can be adjusted by irradiating these members with ultraviolet rays before forming the first cover layer 13 on the substrate 11B, the first wiring 21B, and the second wiring 22B or by forming a release agent layer provided in contact with these members. Since an effect of the other configurations are the same as that of the first embodiment, description of the effect will be omitted.

In the present embodiment, the substrate 11B and the first wiring 21B, and the first wiring 21B and the first cover layer are in contact with each other, respectively, but the present disclosure is not limited thereto, and at least one of the interface between the substrate 11B and the first wiring 21B and the interface between the first wiring 21B and the first cover layer may be peeled off. In this case, a void may exist at least one of between the substrate 11B and the first wiring 21B and between the first wiring 21B and the first cover layer.

### Fourth Embodiment

FIG. 6 is an enlarged sectional view illustrating a part of a fourth embodiment of the stretchable wiring board, and specifically corresponds to FIG. 3. The fourth embodiment is different from the second embodiment in that a first cover layer is further provided. This different configuration will be described below. The other configurations are the same as those of the second embodiment, and are denoted by the same reference symbols as those of the second embodiment, and omitted from description.

As illustrated in FIG. 6, a stretchable wiring board 1C of the fourth embodiment further includes a first cover layer 13C laminated on a fourth main surface 122C. A first wiring 21C and a second wiring 22C are disposed between a substrate 11C and the first cover layer 13C. Thus, the first wiring 21C and the second wiring 22C can be protected. The substrate 11C, the buffer layer 12C, and the first cover layer 13C correspond to an example of members included in the main body (stress relaxation portion).

The configurations regarding the constituent material and properties such as stretching ratio, Young's modulus, and thickness of the first cover layer 13C and the peeling strength between the first cover layer 13C and the first wiring 21C or the second wiring 22C are the same as the configurations in the third embodiment.

In a section orthogonal to the extending direction of the first wiring 21C, the first cover layer 13C preferably covers a portion where the first wiring 21C and the buffer layer 12C are not in contact with each other in the periphery of the first wiring 21C.

At least one of a peeling strength of an interface S10 between the substrate 11C and the buffer layer 12C, a peeling strength of an interface S11 between the buffer layer 12C and the first wiring 21C, a peeling strength of an interface S12 between the buffer layer 12C and the second wiring 22C, a peeling strength of an interface S13 between the first wiring 21C and the first cover layer 13C, and a peeling strength of an interface S14 between the second wiring 22C and the first cover layer 13C is smaller than a peeling strength of an interface S0 between the first wiring 21C and the second wiring 22C. Therefore, when stress is applied in a direction orthogonal to the fourth main surface 122C, at least one of the interface S10 between the substrate 11C and the buffer layer 12C, the interface S11 between the buffer layer 12C and the first wiring 21C, the interface S12 between the buffer layer 12C and the second wiring 22C, the interface S13 between the first wiring 21C and the first cover layer 13C, and the interface S14 between the second wiring 22C and the first cover layer 13C is peeled off, and contact at the interface so between the first wiring 21C and the second wiring 22C is maintained. Thus, the first wiring 21C and the second wiring 22C are protected by the buffer layer 12C and the first cover layer 13C, and the electrical connection between the first wiring 21C and the second wiring 22C can be maintained.

A peeling strength between the buffer layer 12C and the first cover layer 13C is smaller than a peeling strength between the first wiring 21C and the second wiring 22C. Therefore, when stress is applied in a direction orthogonal to the fourth main surface 122C, the buffer layer 12C and the first cover layer 13C are peeled off from each other, and peeling between the first wiring 21C and the second wiring 22C is suppressed. Thus, the first wiring 21C and the second wiring 22C are protected by the first cover layer 13C, and the electrical connection between the first wiring 21C and the second wiring 22C can be maintained.

The peeling strength between the buffer layer 12C and the first cover layer 13C can be measured in accordance with JIS K 5600 May 6. The peeling strength between the buffer layer 12C and the first cover layer 13C is preferably 0 to 4.

The peeling strength between the buffer layer 12C and the first cover layer 13C can be adjusted by irradiating the buffer layer 12C with ultraviolet rays before forming the first cover layer 13C on the buffer layer 12C or by forming a release agent layer provided in contact with the buffer layer 12C. Since an effect of the other configurations are the same as that of the second embodiment, description of the effect will be omitted.

In the present embodiment, the substrate 11C and the buffer layer 12C, the buffer layer 12C and the first wiring 21C, and the first wiring 21C and the first cover layer 13C are in contact with each other, respectively, but the present disclosure is not limited thereto, and at least one of the interface between the substrate 11C and the buffer layer 12C, the interface between the buffer layer 12C and the first wiring 21C, and the interface between the first wiring 21C and the first cover layer 13C may be peeled off. In this case, a void may exist at least one of between the substrate 11C and the buffer layer 12C, between the buffer layer 12C and the first wiring 21C, and between the first wiring 21C and the first cover layer 13C.

### Fifth Embodiment

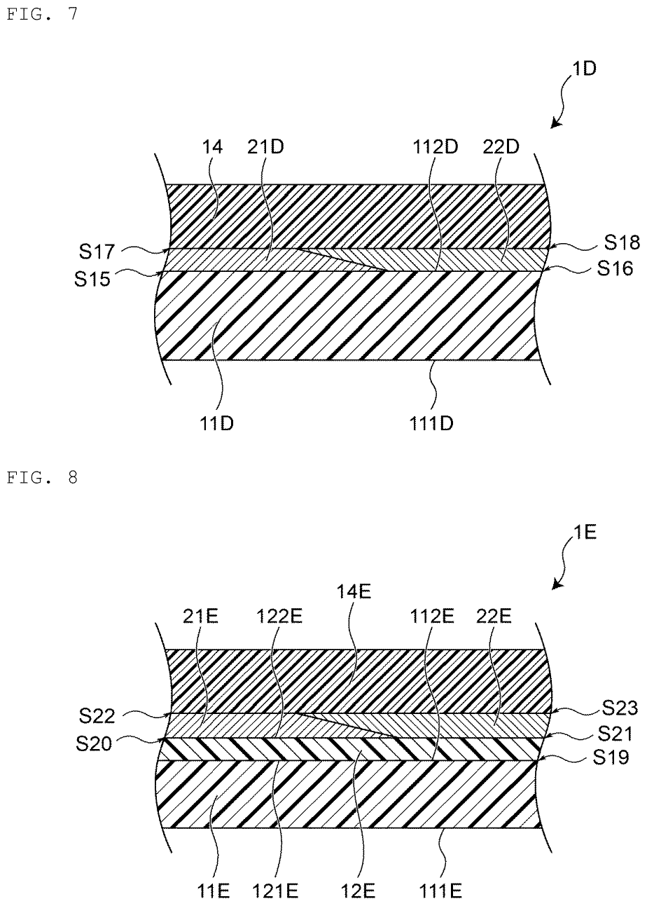

FIG. 7 is an enlarged sectional view illustrating a part of a fifth embodiment of the stretchable wiring board, and specifically corresponds to FIG. 3. The fifth embodiment is different from the third embodiment in that a second cover layer is further provided. This different configuration will be described below. The other configurations are the same as those of the third embodiment, and are denoted by the same reference symbols as those of the third embodiment, and omitted from description.

As illustrated in FIG. 7, a stretchable wiring board 1D of the fifth embodiment further includes a second cover layer 14 laminated on a second main surface 112D. A first wiring 21D and a second wiring 22D are disposed between a substrate 11D and the second cover layer 14. Thus, the first wiring 21D and the second wiring 22D can be further protected. The substrate 11D and the second cover layer 14 correspond to an example of members included in the main body (stress relaxation portion).

The second cover layer 14 is formed of a stretchable resin material, for example, ionomer resin, polyester resin, styrene resin, olefin resin, epoxy resin, urethane resin, acrylic resin, or silicone resin, and is preferably formed of urethane resin. Examples of the urethane resin include thermoplastic polyurethane (TPU). Examples of the styrene resin include styrene-butadiene-styrene copolymer resin (SBS). The second cover layer 14 may be the same member as the first cover layer.

The second cover layer 14 is preferably poorly stretchable, and a stretching ratio of the second cover layer 14 is preferably 100% or less. Thus, the first wiring 21D and the second wiring 22D can be appropriately fixed. Young's modulus of the second cover layer 14 is 100 MPa or more, preferably 10000 MPa or less. Thus, the first wiring 21D and the second wiring 22D can be further protected. A thickness of the second cover layer 14 is, for example, 10 to 50 μm.

The second cover layer 14 preferably has waterproofness. As a result, penetration of moisture can be prevented, and reliability of the stretchable wiring board 1D can be maintained.

In a section orthogonal to the extending direction of the first wiring 21D, the second cover layer 14 preferably covers a portion where the first wiring 21D and the substrate 11D are not in contact with each other in the periphery of the first wiring 21D.

At least one of a peeling strength of an interface S15 between the substrate 11D and the first wiring 21D, a peeling strength of an interface S16 between the substrate 11D and the second wiring 22D, a peeling strength of an interface S17 between the first wiring 21D and the second cover layer 14, and a peeling strength of an interface S18 between the second wiring 22D and the second cover layer 14 is smaller than a peeling strength of an interface S0 between the first wiring 21D and the second wiring 22D. Therefore, when stress is applied in a direction orthogonal to the second main surface 12D, at least one of the interface S15 between the substrate 11D and the first wiring 21D, the interface S16 between the substrate 11D and the second wiring 22D, the interface S17 between the first wiring 21D and the second cover layer 14, and the interface S18 between the second wiring 22D and the second cover layer 14 is first peeled off, and peeling between the first wiring 21D and the second wiring 22D is suppressed. Thus, the first wiring 21D and the second wiring 22D are protected by the second cover layer 14, and the electrical connection between the first wiring 21D and the second wiring 22D can be maintained.

A peeling strength between the substrate 11D and the first wiring 21D or the second wiring 22D is preferably smaller than a peeling strength between the substrate 11D and the second cover layer 14. Thus, when stress is applied in a direction orthogonal to the second main surface 112D, the substrate 11D and the first wiring 21D or the second wiring 22D are peeled off from each other, contact between the substrate 11D and the second cover layer 14 is maintained, and the first wiring 21D and the second wiring 22D can be protected.

A peeling strength between the second cover layer 14 and the second wiring 22D is smaller than a peeling strength between the first wiring 21D and the second wiring 22D. Therefore, when stress is applied in a direction orthogonal to the second main surface 112D, the second cover layer 14 and the second wiring 22D are peeled off from each other, and peeling between the first wiring 21D and the second wiring 22D is suppressed. Thus, the first wiring 21D and the second wiring 22D are protected by the second cover layer 14, and the electrical connection between the first wiring 21D and the second wiring 22D can be maintained.

The peeling strength between the second cover layer 14 and the first wiring 21D is different from the second cover layer 14 and the second wiring 22D. Therefore, when stress is applied in a direction orthogonal to the second main surface 112D, at least one of the first wiring 21D and the second wiring 22D is first peeled off from the second cover layer 14, peeling between the second cover layer 14 and the wiring is minimized, and the other thereof is kept in contact with the second cover layer 14. Therefore, at least a part of the wiring is protected by the second cover layer 14. Thus, penetration of moisture can be prevented, and reliability of the stretchable wiring board 1D can be maintained.

A peeling strength between the substrate 11D and the second cover layer 14 is smaller than a peeling strength between the first wiring 21D and the second wiring 22D. Therefore, when stress is applied in a direction orthogonal to the second main surface 112D, the substrate 11D and the second cover layer 14 are peeled off from each other, and peeling between the first wiring 21D and the second wiring 22D is suppressed. Thus, the first wiring 21D and the second wiring 22D are protected by the second cover layer 14, and the electrical connection between the first wiring 21D and the second wiring 22D can be maintained.

The peeling strength between the second cover layer 14 and the first wiring 21D, the peeling strength between the second cover layer 14 and the second wiring 22D, and the peeling strength between the substrate 11D and the second cover layer 14 can all be measured in accordance with JIS K 5600 May 6. The peeling strength between the second cover layer 14 and the first wiring 21D and the peeling strength between the second cover layer 14 and the second wiring 22D are each preferably 0 to 4. The peeling strength between the substrate 11D and the second cover layer 14 is preferably 0 to 4.

The peeling strength between the second cover layer 14 and the first wiring 21D, the peeling strength between the second cover layer 14 and the second wiring 22D, and the peeling strength between the substrate 11D and the second cover layer 14 can be adjusted by irradiating these members with ultraviolet rays before forming the second cover layer 14 on the substrate 11D, the first wiring 21D, and the second wiring 22D or by forming a release agent layer provided in contact with these members. Since an effect of the other configurations are the same as that of the first embodiment, description of the effect will be omitted.

In the present embodiment, the substrate 11D and the first wiring 21D, and the first wiring 21D and the second cover layer 14 are in contact with each other, respectively, but the present disclosure is not limited thereto, and at least one of the interface between the substrate 11D and the first wiring 21D and the interface between the first wiring 21D and the second cover layer 14 may be peeled off. In this case, a void may exist any one of between the substrate 11D and the first wiring 21D and between the first wiring 21D and the second cover layer 14.

### Sixth Embodiment

FIG. 8 is an enlarged sectional view illustrating a part of a sixth embodiment of the stretchable wiring board, and specifically corresponds to FIG. 3. The sixth embodiment is different from the second embodiment in that a second cover layer is further provided. This different configuration will be described below. The other configurations are the same as those of the second embodiment, and are denoted by the same reference symbols as those of the second embodiment, and will be omitted from description.

As illustrated in FIG. 8, a stretchable wiring board 1E of the sixth embodiment further includes a second cover layer 14E laminated on a fourth main surface 122E. A first wiring 21E and a second wiring 22E are disposed between a substrate 11E and the second cover layer 14E. Thus, the first wiring 21E and the second wiring 22E can be protected. The substrate 11E, the buffer layer 12E, and the second cover layer 14E correspond to an example of members included in the main body (stress relaxation portion).

The configurations regarding the constituent material and properties such as stretching ratio, Young's modulus, and thickness of the second cover layer 14E and the peeling strength between the second cover layer 14E and the first wiring 21E or the second wiring 22E are the same as the configurations in the fifth embodiment.

In a section orthogonal to the extending direction of the first wiring 21E, the second cover layer 14E preferably covers a portion where the first wiring 21E and the buffer layer 12E are not in contact with each other in the periphery of the first wiring 21E.

At least one of a peeling strength of an interface S19 between the substrate 11E and the buffer layer 12E, a peeling strength of an interface S20 between the buffer layer 12E and the first wiring 21E, a peeling strength of an interface S21 between the buffer layer 12E and the second wiring 22E, a peeling strength of an interface S22 between the first wiring 21E and the second cover layer 14E, and a peeling strength of an interface S23 between the second wiring 22E and the second cover layer 14E is smaller than a peeling strength of an interface S0 between the first wiring 21E and the second wiring 22E. Therefore, when stress is applied in a direction orthogonal to the fourth main surface 122E, at least one of the interface S19 between the substrate 11E and the buffer layer 12E, the interface S20 between the buffer layer 12E and the first wiring 21E, the interface S21 between the buffer layer 12E and the second wiring 22E, the interface S22 between the first wiring 21E and the second cover layer 14E, and the interface S23 between the second wiring 22E and the second cover layer 14E is first peeled off, and peeling between the first wiring 21E and the second wiring 22E is suppressed. Thus, the first wiring 21E and the second wiring 22E are protected by the buffer layer 12E and the second cover layer 14E, and the substrate can suppress excessive deformation of the wiring at a place where the shape of the substrate or the wiring needs to be maintained, such as an electronic component.

A peeling strength between the buffer layer 12E and the second cover layer 14E is smaller than a peeling strength between the first wiring 21E and the second wiring 22E. Therefore, when stress is applied in a direction orthogonal to the fourth main surface 122E, the buffer layer 12E and the second cover layer 14E are peeled off from each other, and peeling between the first wiring 21E and the second wiring 22E is suppressed. Thus, the first wiring 21E and the second wiring 22E are protected by the second cover layer 14E, and the electrical connection between the first wiring 21E and the second wiring 22E can be maintained.

A peeling strength between the buffer layer 12E and the first wiring 21E or the second wiring 22E is preferably smaller than a peeling strength between the buffer layer 12E and the second cover layer 14E. Thus, when stress is applied in a direction orthogonal to the fourth main surface 122E, the buffer layer 12E and the first wiring 21E or the second wiring 22E are peeled off from each other, contact between the buffer layer 12E and the second cover layer 14E is maintained, and the first wiring 21E and the second wiring 22E can be protected.

The peeling strength between the buffer layer 12E and the second cover layer 14E can be measured in accordance with JIS K 5600 May 6. The peeling strength between the buffer layer 12E and the second cover layer 14E is preferably 0 to 4.

The peeling strength between the buffer layer 12E and the second cover layer 14E can be adjusted by irradiating the buffer layer 12E with ultraviolet rays before forming the second cover layer 14E on the buffer layer 12E or by forming a release agent layer provided in contact with the buffer layer 12E. Since an effect of the other configurations are the same as that of the second embodiment, description of the effect will be omitted.

In the present embodiment, the substrate 11E and the buffer layer 12E, the buffer layer 12E and the first wiring 21E, and the first wiring 21E and the second cover layer 14 are in contact with each other, respectively, but the present disclosure is not limited thereto, and at least one of the interface between the substrate 11E and the buffer layer 12E, the interface between the buffer layer 12E and the first wiring 21E, and the interface between the first wiring 21E and the second cover layer 14 may be peeled off. In this case, a void may exist at least one of between the substrate 11E and the buffer layer 12E, between the buffer layer 12E and the first wiring 21E, and between the first wiring 21E and the second cover layer 14.

### Seventh Embodiment

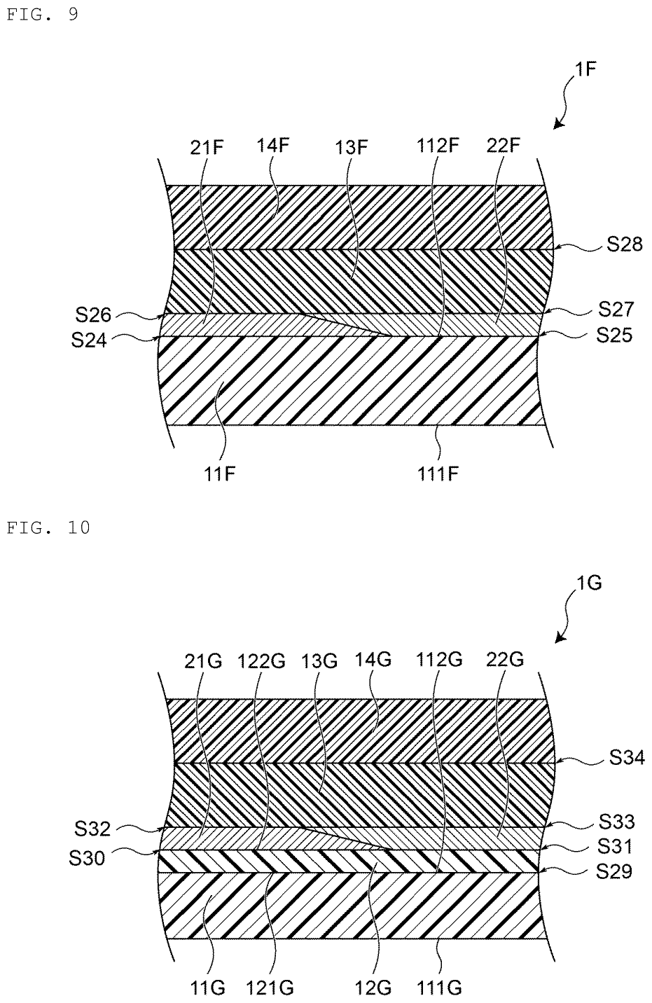

FIG. 9 is an enlarged sectional view illustrating a part of a seventh embodiment of the stretchable wiring board, and specifically corresponds to FIG. 3. The seventh embodiment is different from the third embodiment in that a second cover layer is further provided. This different configuration will be described below. The other configurations are the same as those of the third embodiment, and are denoted by the same reference symbols as those of the third embodiment, and will be omitted from description.

As illustrated in FIG. 9, a stretchable wiring board 1F of the seventh embodiment further includes a first cover layer 13F and a second cover layer 14F laminated on a second main surface 112F, and the second cover layer 14F is laminated on the first cover layer 13F. Therefore, excessive deformation of the substrate 11F or the wiring can be suppressed at a place where the shape of the substrate 11F or the wiring needs to be maintained. Also when deformation occurs, the deformation can be absorbed by the flexible first cover layer 13F, and the first wiring 21F and the second wiring 22F can be protected. The substrate 11F, the first cover layer 13F, and the second cover layer 14F correspond to an example of members included in the main body (stress relaxation portion).

The configurations regarding the constituent material and properties such as stretching ratio, Young's modulus, and thickness of the second cover layer 14F are the same as the configurations in the fifth embodiment.

In the present embodiment, on the second main surface 112F, a portion not covered with the first cover layer 13F may exist, or a portion where the substrate 11F and the second cover layer 14F are in contact with each other may exist.

At least one of a peeling strength of an interface S24 between the substrate 11F and the first wiring 21F, a peeling strength of an interface S25 between the substrate 11F and the second wiring 22F, a peeling strength of an interface S26 between the first wiring 21F and the first cover layer 13F, a peeling strength of an interface S27 between the second wiring 22F and the first cover layer 13F, and a peeling strength of an interface S28 between the first cover layer 13F and the second cover layer 14F is smaller than a peeling strength of an interface S0 between the first wiring 21F and the second wiring 22F. Therefore, when stress is applied in a direction orthogonal to the second main surface 112F, at least one of the interface S24 between the substrate 11F and the first wiring 21F, the interface S25 between the substrate 11F and the second wiring 22F, the interface S26 between the first wiring and the first cover layer, the interface S27 between the second wiring and the first cover layer, and the interface S28 between the first cover layer and the second cover layer is first peeled off, and contact between the first wiring 21F and the second wiring 22F can be maintained. Thus, the first wiring 21F and the second wiring 22F are protected by the first cover layer 13F and the second cover layer 14F, and excessive deformation of the substrate or the wiring can be suppressed at a place where the shape of the substrate or the wiring needs to be maintained. Also when deformation occurs, the deformation can be absorbed by the flexible first cover layer 13F, and the first wiring 21F and the second wiring 22F can be protected.

A peeling strength between the first cover layer 13F and the second cover layer 14F is smaller than a peeling strength between the first wiring 21F and the second wiring 22F. Therefore, when stress is applied in a direction orthogonal to the second main surface 112F, the first cover layer 13F and the second cover layer 14F are peeled off from each other, and peeling between the first wiring 21F and the second wiring 22F is suppressed. Thus, the first wiring 21F and the second wiring 22F are protected by the first cover layer 13F and the second cover layer 14F, and the electrical connection between the first wiring 21F and the second wiring 22F can be maintained.

The peeling strength between the first cover layer 13F and the second cover layer 14F can be measured in accordance with JIS K 5600 May 6. The peeling strength between the first cover layer 13F and the second cover layer 14F is preferably 0 to 4.

The peeling strength between the first cover layer 13F and the second cover layer 14F can be adjusted by irradiating the first cover layer 13F with ultraviolet rays before forming the second cover layer 14F on the first cover layer 13F or by forming a release agent layer provided in contact with the first cover layer 13F. Since an effect of the other configurations are the same as that of the third embodiment, description of the effect will be omitted.

In the present embodiment, the substrate 11F and the first wiring 21F, the first wiring 21F and the first cover layer 13F, and the first cover layer 13F and the second cover layer 14F are in contact with each other, respectively, but the present disclosure is not limited thereto, and at least one of the interface between the substrate 11F and the first wiring 21F, the interface between the first wiring 21F and the first cover layer 13F, and the interface between the first cover layer 13F and the second cover layer 14F may be peeled off. In this case, a void may exist at least one of between the substrate 11F and the first wiring 21F, between the first wiring 21F and the first cover layer 13F, and between the first cover layer 13F and the second cover layer 14F.

### Eighth Embodiment

FIG. 10 is an enlarged sectional view illustrating a part of an eighth embodiment of the stretchable wiring board, and specifically corresponds to FIG. 3. The eighth embodiment is different from the fourth embodiment in that a second cover layer is further provided. This different configuration will be described below. The other configurations are the same as those of the fourth embodiment, and are denoted by the same reference symbols as those of the fourth embodiment, and will be omitted from description.

As illustrated in FIG. 10, a stretchable wiring board 1G of the eighth embodiment further includes a first cover layer 13G and a second cover layer 14G laminated on a second main surface 112G, and the second cover layer 14G is laminated on the first cover layer 13G. Therefore, excessive deformation of the substrate 11G or the wiring can be suppressed at a place where the shape of the substrate 11G or the wiring needs to be maintained. Also when deformation occurs, the deformation can be absorbed by the flexible first cover layer 13G, and the first wiring 21G and the second wiring 22G can be protected. The substrate 11G, the buffer layer 12G, the first cover layer 13G, and the second cover layer 14G correspond to an example of members included in the main body (stress relaxation portion).

The constituent material and properties such as stretching ratio, Young's modulus, and thickness of the second cover layer 14G are the same as the configurations in the fifth embodiment.

In the present embodiment, on the second main surface 112G, a region not covered with the first cover layer 13G may exist, or a region where the substrate 11G and the second cover layer 14G are in direct contact with each other may exist.

At least one of a peeling strength of an interface S29 between the substrate 11G and the buffer layer 12G, a peeling strength of an interface S30 between the buffer layer 12G and the first wiring 21G, a peeling strength of an interface S31 between the buffer layer 12G and the second wiring 22G, a peeling strength of an interface S32 between the first wiring 21G and the first cover layer 13G, a peeling strength of an interface S33 between the second wiring 22G and the first cover layer 13G, and a peeling strength of an interface S34 between the first cover layer 13G and the second cover layer 14G is smaller than a peeling strength of an interface S0 between the first wiring 21G and the second wiring 22G. Therefore, when stress is applied in a direction orthogonal to the fourth main surface 122G, at least one of the interface S29 between the substrate 11G and the buffer layer 12G, the interface S30 between the buffer layer 12G and the first wiring 21G, the interface S31 between the buffer layer 12G and the second wiring 22G, the interface S32 between the first wiring 21G and the first cover layer 13G, the interface S33 between the second wiring 22G and the first cover layer 13G, and the interface S34 between the first cover layer and the second cover layer is first peeled off, and contact between the first wiring 21G and the second wiring 22G can be maintained. Thus, the first wiring 21G and the second wiring 22G are protected by the buffer layer 12G, the first cover layer 13G, and the second cover layer 14G, and excessive deformation of the substrate or the wiring can be suppressed at a place where the shape of the substrate or the wiring needs to be maintained. Also when deformation occurs, the deformation can be absorbed by the flexible first cover layer 13G, and the first wiring 21G and the second wiring 22G can be protected.

A peeling strength between the first cover layer 13G and the second cover layer 14G is smaller than a peeling strength between the first wiring 21G and the second wiring 22G. Therefore, when stress is applied in a direction orthogonal to the second main surface 112G, the first cover layer 13G and the second cover layer 14G are peeled off from each other, and peeling between the first wiring 21G and the second wiring 22G is suppressed. Thus, the first wiring 21G and the second wiring 22G are protected by the first cover layer 13G and the second cover layer 14G, and the electrical connection between the first wiring 21G and the second wiring 22G can be maintained.

The peeling strength between the first cover layer 13G and the second cover layer 14G can be measured in accordance with JIS K 5600 May 6. The peeling strength between the first cover layer 13G and the second cover layer 14G is preferably 0 to 4.

The peeling strength between the first cover layer 13G and the second cover layer 14G can be adjusted by irradiating the first cover layer 13G with ultraviolet rays before forming the second cover layer 14G on the first cover layer 13G or by forming a release agent layer provided in contact with the first cover layer 13G. Since an effect of the other configurations are the same as that of the fourth embodiment, description of the effect will be omitted.

In the present embodiment, the substrate 11G and the buffer layer 12G, the buffer layer 12G and the first wiring 21G, the first wiring 21G and the first cover layer 13G, and the first cover layer 13G and the second cover layer 14G are in contact with each other, respectively, but the present disclosure is not limited thereto, and at least one of the interface between the substrate 11G and the buffer layer 12G, the interface between the buffer layer 12G and the first wiring 21G, the interface between the first wiring 21G and the first cover layer 13G, and the interface between the first cover layer 13G and the second cover layer 14G may be peeled off. In this case, a void may exist at least one of between the substrate 11G and the buffer layer 12G, between the buffer layer 12G and the first wiring 21G, between the first wiring 21G and the first cover layer 13G, and between the first cover layer 13G and the second cover layer 14G.

In the present embodiment, the second cover layer 14G is disposed on the first cover layer 13G, but the present disclosure is not limited thereto, and the first cover layer 13G may be disposed on the second cover layer 14G. In this case, at least one of a peeling strength between the substrate 11G and the buffer layer 12G, a peeling strength between the buffer layer 12G and the first wiring 21G, a peeling strength between the first wiring 21G and the second cover layer 14G, and a peeling strength between the second cover layer 14G and the first cover layer 13G is smaller than a peeling strength between the first wiring 21G and the second wiring 22G.

### Ninth Embodiment

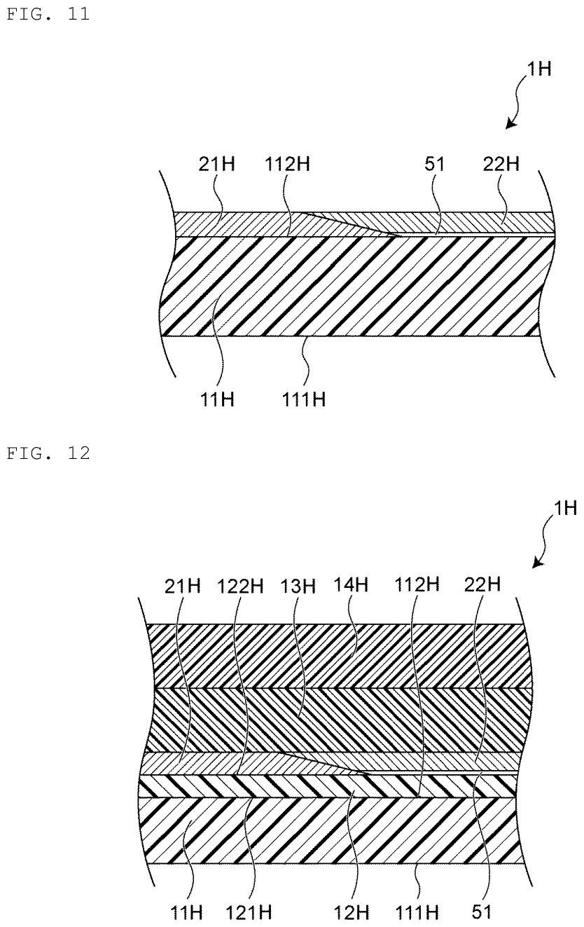

FIG. 11 is an enlarged sectional view illustrating a part of a ninth embodiment of the stretchable wiring board, and specifically corresponds to FIG. 3. The ninth embodiment is different from the first embodiment in that a void is provided between the substrate and the second wiring. This different configuration will be described below. The other configurations are the same as those of the first embodiment, and are denoted by the same reference symbols as those of the first embodiment, and will be omitted from description.

As illustrated in FIG. 11, a stretchable wiring board 1H of the ninth embodiment includes a void 51 between a substrate 11H and a second wiring 22H. Thus, when stress is applied in a direction orthogonal to the second main surface 112H, the stress is absorbed by the void 51, so that peeling between the first wiring 21H and the second wiring 22H can be suppressed. Therefore, the electrical connection between the first wiring 21H and the second wiring 22H can be maintained. The substrate 11H corresponds to an example of a main body (stress relaxation portion).

In the present embodiment, the void 51 is provided at an interface S2 between the substrate 11H and the second wiring 22H, but the present disclosure is not limited thereto, and the void 51 may be provided at an interface S1 between the substrate 11H and the first wiring 21H. In the first to eighth embodiments, the void 51 may be provided at an arbitrary position among interfaces S1 to S34 illustrated in FIGS. 3 to 10. For example, as illustrated in FIG. 12, in the eighth embodiment, the void 51 may be provided at a position of the interface S31 between the buffer layer 12G and the second wiring 22G. Also in this case, when the stretchable wiring board 1H is bent and stress is applied in a direction orthogonal to the fourth main surface 122G, the stress is absorbed by the void 51, so that peeling between the first wiring 21H and the second wiring 22H can be suppressed. Therefore, the electrical connection between the first wiring 21H and the second wiring 22H can be maintained. In this case, the substrate 11H, the buffer layer 12H, the first cover layer 13H, and the second cover layer 14H correspond to an example of members included in the main body (stress relaxation portion). Since an effect of the other configurations are the same as that of the first embodiment, description of the effect will be omitted.

In the ninth embodiment, a void is provided between the substrate and the first wiring or the second wiring, but the present disclosure is not limited thereto, and a void may be provided between the substrate and the buffer layer, between the buffer layer and the first wiring or the second wiring, between the first wiring or the second wiring and the first cover layer, between the first wiring or the second wiring and the second cover layer, or between the first cover layer and the second cover layer.

### Tenth Embodiment

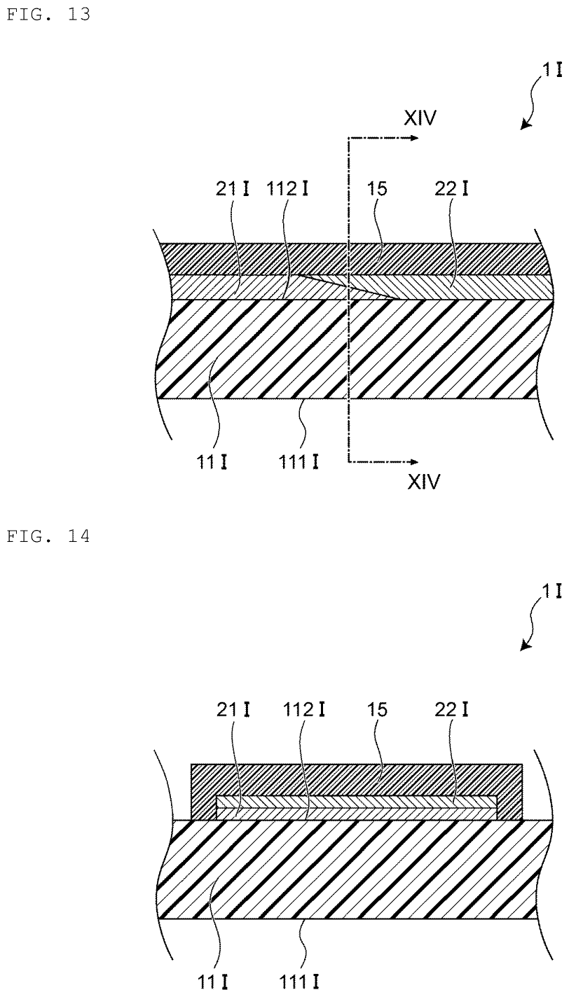

FIG. 13 is an enlarged sectional view illustrating a part of a tenth embodiment of the stretchable wiring board, and specifically corresponds to FIG. 3. FIG. 14 is a sectional view taken along XIV-XIV of FIG. 13. The tenth embodiment is different from the first embodiment in that a hard portion is further provided. This different configuration will be described below. The other configurations are the same as those of the fifth embodiment, and are denoted by the same reference symbols as those of the fifth embodiment, and will be omitted from description.

As illustrated in FIGS. 13 and 14, a stretchable wiring board 1I of the tenth embodiment includes a substrate 11I and a first wiring 21I and a second wiring 22I disposed on a second main surface 112I of the substrate 11I, and further includes a hard portion 15. The hard portion 15 covers a portion where the first wiring 21I and the second wiring 22I are in contact with each other and is in contact with the substrate 11I. As a result, end edges of the first wiring 21I and the second wiring 22I are covered with the hard portion 15, and penetration of moisture to the first wiring 21I and the second wiring 22I can be suppressed. The substrate 11I corresponds to an example of a main body (stress relaxation portion).

The above effects will be specifically described. As described above, by providing the main body (stress relaxation portion), peeling of the connection portion between the first wiring 21 and the second wiring 22 can be suppressed, and reliability of connection between the first wiring 21 and the second wiring 22 can be improved. On the other hand, when there is a peeled portion in the main body (stress relaxation portion), moisture intrudes from the portion, and ion migration may occur.

By providing the hard portion to cover the end edge of the stretchable wiring as illustrated in FIGS. 13 and 14, penetration of moisture can be suppressed when a part of the main body (stress relaxation portion) is peeled off.

The constituent material of the hard portion 15 is not particularly limited, but is preferably a material having a higher Young's modulus than the Young's modulus of the stretchable substrate 1I. When the hard portion 15 has a higher Young's modulus than that of the stretchable substrate 1I, penetration of moisture to the first wiring 21I and the second wiring 22I can be more reliably suppressed. Examples of a material having a higher Young's modulus than that of the stretchable substrate 1I include polyvinyl chloride, polyethylene, polystyrene, polycarbonate, polyvinylidene fluoride, polyimide, liquid crystal polymer, polytetrafluoroethylene, and elastomer-based resin such as phenol resins, epoxy-based resins, urethane-based resin, acrylic-based resins, silicone-based resins, and styrene-butadiene-based resins.

The hard portion 15 is preferably poorly stretchable, and a stretching ratio of the hard portion 15 is preferably 100% or less. Thus, the first wiring 21D and the second wiring 22D can be appropriately fixed. Young's modulus of the hard portion 15 is 100 MPa or more, preferably 10,000 MPa or less. Thus, penetration of moisture can be further suppressed. A thickness of the hard portion 15 is, for example, 10 to 50 μm.

The hard portion 15 preferably has waterproofness. As a result, penetration of moisture can be prevented, and reliability of the stretchable wiring board 1I can be maintained.

The hard portion 15 covers a portion where the first wiring 21I and the second wiring 22I are connected to each other and is in contact with the substrate 11I. As a result, the hard portion 15 protects a portion where the first wiring 21I and the second wiring 22I are in contact with each other, and the first wiring 21I and the second wiring 22I located inside the hard portion 15 are not exposed to the outside, so that penetration of moisture to the first wiring 21I and the second wiring 22I can be prevented.

The present embodiment corresponds to the first embodiment, but is not limited thereto, and may be combined with the configurations of the second to eighth embodiments. For example, in the second embodiment, the hard portion 15 is further provided, and the hard portion may cover a portion where the first wiring and the second wiring are in contact with each other and may be in contact with the substrate. In this case, the end portion of the buffer layer and the end edges of the first wiring and the second wiring are all covered with the hard portion. Therefore, penetration of moisture to the first wiring and the second wiring can be suppressed. Similarly, in the tenth embodiment, the hard portion is further provided, and the hard portion may cover a portion where the first wiring and the second wiring are in contact with each other and may be in contact with the substrate. In this case, the end portion of the buffer layer, the end edges of the first wiring and the second wiring, and the end portions of the first cover layer and the second cover layer are all covered with the hard portion. Therefore, penetration of moisture to the first wiring and the second wiring can be suppressed. Since an effect of the other configurations are the same as that of the fifth embodiment, description of the effect will be omitted.

Note that the present disclosure is not limited to the above-described embodiments, and can be changed in design without departing from the gist of the present disclosure. For example, the characteristic features of the first to tenth embodiments may be combined in various ways.

In the embodiments, the buffer layer has waterproofness, but the present disclosure is not limited thereto, and at least one of the substrate, the first cover layer, the second cover layer, and the hard portion may have waterproofness. In any case, the substrate, the buffer layer, the first cover layer, the second cover layer, or the hard portion which has waterproofness corresponds to an example of the waterproof layer.

In the embodiments, the number of layers of each of the substrate, the buffer layer, the first cover layer, the second cover layer, and the hard portion is one, but the present disclosure is not limited thereto, and the total number thereof can be freely increased or decreased. In this case, the peeling strength in at least one combination of two adjacent layers (any one of the substrate, the buffer layer, the first cover layer, the second cover layer, the first wiring, and the second wiring) may be smaller than the peeling strength between the first wiring and the second wiring.

Each layer included in the main body (stress relaxation portion) is not an essential configuration of the present disclosure. Specifically, the main body (stress relaxation portion) may be constituted only by the substrate and the hard portion, or may be constituted only by the substrate and the second cover layer. The same applies to other combinations.

### DESCRIPTION OF REFERENCE SYMBOLS

1, 1A, 1B, 1C, 1D, 1E, 1F, 1G, 1H, 1I: Stretchable wiring board
11, 11A, 11B, 11C, 11D, 11E, 11F, 11G, 11H, 11I: Substrate
111, 111A, 111B, 111C, 111D, 111E, 111F, 111G, 111H,
111I: First main surface
112, 112A, 112B, 112C, 112D, 112E, 112F, 112G, 112H, 112I: Second main surface
12, 12C, 12E, 12G: Buffer layer
121, 121C, 121E, 121G: Third main surface
122, 122C, 122E, 122G: Fourth main surface
13, 13C, 13F, 13G: First cover layer
14, 14E, 14F, 14G, 14I: Second cover layer
15: Hard portion
21, 21A, 21B, 21C, 21D, 21E, 21F, 21G, 21H, 21I: First wiring
22, 22A, 22B, 22C, 22D, 22E, 22F, 22G, 22H, 22I: Second wiring
23: Third wiring
24: Fourth wiring
31: Electronic component
41: Insulating layer
51: Void
S31 to S34: Interface

1. A stretchable wiring board comprising:
a main body;
a stretchable first wiring on the main body; and
a stretchable second wiring on the main body and connected to the stretchable first wiring, wherein
a first peeling strength of the main body is smaller than a second peeling strength between the stretchable first wiring and the stretchable second wiring.

2. The stretchable wiring board according to claim 1, wherein at least one of a third peeling strength between the main body and the stretchable first wiring and a fourth peeling strength between the main body and the stretchable second wiring is smaller than the second peeling strength between the stretchable first wiring and the stretchable second wiring.

3. The stretchable wiring board according to claim 1, wherein
the main body includes a plurality of members laminated on each other, and
at least one of a third peeling strength between the main body and the stretchable first wiring, a fourth peeling strength between the main body and the stretchable second wiring, and a fifth peeling strength between two adjacent members of the plurality of members is smaller than the second peeling strength between the stretchable first wiring and the stretchable second wiring.

4. The stretchable wiring board according to claim 1, wherein the plurality of members of the main body include at least two of:
a stretchable substrate;
a buffer layer between the stretchable substrate and the stretchable first wiring and the stretchable second wiring;
a first cover layer over the stretchable first wiring and the stretchable second wiring;
a second cover layer over the first cover layer; and
a hard portion covering at least one of the stretchable first wiring and the stretchable second wiring.

5. The stretchable wiring board according to claim 1, wherein a third peeling strength between the main body and the stretchable first wiring is different from a fourth peeling strength between the main body and the stretchable second wiring.

6. The stretchable wiring board according to claim 1, wherein the main body includes a stretchable substrate, and
the stretchable first wiring and the stretchable second wiring are on the stretchable substrate.

7. The stretchable wiring board according to claim 1, wherein the main body includes a stretchable substrate and a waterproof layer.

8. The stretchable wiring board according to claim 7, wherein the waterproof layer is between the stretchable substrate and the stretchable first wiring and the stretchable second wiring.

9. The stretchable wiring board according to claim 6, further comprising a hard portion covering at least one of the stretchable first wiring and the stretchable second wiring.

10. The stretchable wiring board according to claim 9, wherein the hard portion covers a portion where the stretchable first wiring and the stretchable second wiring are connected to each other and is in contact with the stretchable substrate.

11. A stretchable wiring board comprising:
a main body;
a stretchable first wiring on the main body;
a stretchable second wiring on the main body and connected to the stretchable first wiring; and
a void portion located so as to absorb stress applied to the stretchable wiring board and suppress peeling of at least one of the stretchable first wiring and the stretchable second wiring.

12. The stretchable wiring board according to claim 11, wherein the void portion is located at least one of between the main body and the stretchable first wiring and between the main body and the stretchable second wiring.

13. The stretchable wiring board according to claim 11, wherein at least one of a first peeling strength between the main body and the stretchable first wiring and a second peeling strength between the main body and the stretchable second wiring is smaller than a third peeling strength between the stretchable first wiring and the stretchable second wiring.

14. The stretchable wiring board according to claim 11, wherein the main body includes a plurality of members laminated on each other, and
the void portion is located at least one of between the main body and the stretchable first wiring, between the main body and the stretchable second wiring, and between two adjacent members of the plurality of members.

15. The stretchable wiring board according to claim 14, wherein the plurality of members of the main body include at least two of:
a stretchable substrate;
a buffer layer between the stretchable substrate and the stretchable first wiring and the stretchable second wiring;
a first cover layer over the stretchable first wiring and the stretchable second wiring;
a second cover layer over the first cover layer; and
a hard portion covering at least one of the stretchable first wiring and the stretchable second wiring.

16. The stretchable wiring board according to claim 11, wherein
the main body includes a stretchable substrate, and
the stretchable first wiring and the stretchable second wiring are on the stretchable substrate.

17. The stretchable wiring board according to claim 11, wherein the main body includes a stretchable substrate and a waterproof layer.

18. The stretchable wiring board according to claim 17, wherein the waterproof layer is between the stretchable substrate and the stretchable first wiring and the stretchable second wiring.

19. The stretchable wiring board according to claim 16, further comprising a hard portion covering at least one of the stretchable first wiring and the stretchable second wiring.

20. The stretchable wiring board according to claim 19, wherein the hard portion covers a portion where the stretchable first wiring and the stretchable second wiring are connected to each other and is in contact with the stretchable substrate.
